(19) United States
(12) Patent Application Publication
(10) Pub. No.: US 2026/0344343 A1
(43) Pub. Date: Oct. 29, 2026

(54) METHODS OF CROSS-SECTION IMAGING OF AN INSPECTION VOLUME IN A WAFER

(71) Applicant: Carl Zeiss SMT GmbH, Oberkochen (DE)

(72) Inventors: Alex Buxbaum, San Ramon, CA (US); Eugen Foca, Ellwangen (DE); Chuong Huynh, Quincy, MA (US); Dmitry Klochkov, Schwaebisch Gmuend (DE); Thomas Korb, Schwaebisch Gmuend (DE); Jens Timo Neumann, Aalen (DE); Baohua Niu, Livermore, CA (US)

(21) Appl. No.: 19/731,599

(22) Filed: Jul. 6, 2026

Related U.S. Application Data
(63) Continuation of application No. 19/279,827, filed on Jul. 24, 2025.
Application No. 19/279,827 is a continuation of application No. 17/820,117, filed on Aug. 16, 2022, now Pat. No. 12,557,588.
Application No. 17/820,117 is a continuation of application No. PCT/EP2021/055670, filed on Mar. 5, 2021.
(60) Provisional application No. 63/037,847, filed on Jun. 11, 2020.
(60) Provisional application No. 63/059,438, filed on Jul. 31, 2020.
(60) Provisional application No. 63/145,612, filed on Feb. 4, 2021.

(30) Foreign Application Priority Data
Mar. 13, 2020 (DE) 102020203228.9
May 26, 2020 (DE) 102020206503.9

(51) Int. Cl. H10P 72/00; G06T 7/00; G06T 7/30; G06T 7/50; H01J 37/22; H01J 37/28; H01J 37/305

(52) U.S. Cl. CPC H10P 72/0616; G06T 7/0004; G06T 7/30; G06T 7/50; H01J 37/222; H01J 37/28; H01J 37/3053; G06T 2207/10028; G06T 2207/30148; H01J 2237/226; H01J 2237/24578; H01J 2237/2803

(57) ABSTRACT

The present invention relates to a three-dimensional circuit pattern inspection technique by cross sectioning of integrated circuits and, more particularly, to a method and apparatus for obtaining a 3D volume image of an integrated semiconductor sample. The method employs a feature based alignment of cross section images based on features of an integrated semiconductor sample.

### BACKGROUND OF THE INVENTION

The present invention relates to a three-dimensional circuit pattern inspection and measurement technique by cross sectioning of integrated circuits and, more particularly, to a method and apparatus for obtaining a 3D volume image of an integrated semiconductor sample. The method can be utilized for quantitative metrology, defect detection, defect review, and inspection of an edge shape of the pattern and to derive a line edge roughness or surface roughness of a fine pattern by using a scanning charged particle microscope.

Semiconductor structures are amongst the finest man-made structures and suffer from very few imperfections only. These rare imperfections are the signatures which defect detection or defect review or quantitative metrology devices are looking for. Fabricated semiconductor structures are based on prior knowledge. For example in a logic type samples, metal lines or interconnects are running parallel in metal layers or metal vias run perpendicular to the metal layers. The angle between metal lines or interconnects in different layers is either 0° or 90°. On the other hand, for VNAND type structures it is known that their cross sections are spherical on average.

In the fabrication of integrated circuits, the features size is becoming smaller. The current minimum feature size or critical dimension is below 10 nm, for example 7 nm or 5 nm, and approaching below 3 nm in near future. Therefore, measuring edge shapes of patterns, and to determine the dimensions of features or the line edge roughness with high precision becomes challenging. Edge shapes of patterns or roughness of lines are subject to several influences. Generally, the edge shape of a line or pattern may be subject to the property of involved materials itself, the lithography exposure or any other involved process step, such as etching, deposition, or implantation. The measurement resolution of charged particle systems is typically limited by the sampling raster of individual image or dwell points on the sample, and the charged particle beam diameter. The sampling raster resolution depends on the scan generator and the magnification of the image processing. The typical raster resolution is 2 nm or below, but the raster resolution limit can be reduced with no physical limitation. The charged particle beam diameter has a limited dimension, which depends on the charged particle beam operation conditions and lens. The beam resolution is limited by approximately half of the beam diameter. The resolution can be below 2 nm. However, well known deconvolution techniques can be applied to improve for example edge detection. Despite the high measurement resolution of actual charged particle systems of few, for example below 2 nm, it is challenging to obtain a measurement accuracy in 3D volumes with accuracy better than 10 nm. As an example, reference is made to Dunn, Kubis and Hull “Quantitative Three-Dimensional Analysis using Focused Ion Beam Microscopy” in “Introduction to Focused Ion Beams” edited by Gianuzzi and Stevie (2005). Here, the demonstrated 3D resolution is about 300 nm.

A common way to generate 3D tomographic data from semiconductor samples on nm scale is the so-called slice and image approach elaborated for example by a Cross Beam apparatus. In such an apparatus, two particle optical systems are arranged at an angle. The first particle electron optical system can be a scanning electron microscope (SEM).

The second particle optical system can be a focused ion beam optical system (FIB), using for example gallium (Ga) ions. A focused ion beam (FIB) of Ga ions is used to cut off layers at an edge of a semiconductor sample slice by slice while every cross section is imaged using a scanning electron microscope (SEM). The two particle optical systems might be oriented perpendicular or at an angle between 45° and 90°. FIG. 1 shows a schematic view of the slice and image approach: using a FIB optical column 50, with a focused ion particle beam 51 in y-direction, and scanning in x-y-plane, a thin layer from the cross section through a semiconductor sample 10 is removed to reveal a new front surface 52 as a cross section image plane 11. In a next step, a SEM (not shown) is used for scanning imaging the front surface of the cross section 11. In this example, the SEM optical axis is oriented parallel to the z-direction, and the scanning imaging lines 82 in x-y-plane raster scan the cross section image plane 11 and form cross section images or slices 100. By repetition of this approach trough for example front surfaces 53 and 54, a sequence of 2D cross section images 1000 through the sample in different depths is obtained. The distance dz between two subsequent image slices can be 1 nm-10 nm. From the sequence of these 2D cross section images 1000, a 3D image of the integrated semiconductor structure can be reconstructed.

With the finer detail and the smaller feature sizes in modern integrated circuits, the reconstruction of the 3D tomographic image implies several challenges. Lateral stage drifts or drifts of the SEM column may cause offsets in the lateral positions of the structures from slice to slice. Variations in the FIB cutting rate may cause the intersection surfaces to be at varying distances. Image distortions may lead to cross section images with for example pin-cushion or shear distortion. FIG. 2 shows an example of a reconstruction from x-z-slices from s sequence of x-y cross section images. For sake of simplicity, only three cross section images 100.1, 100.2, 100.3 at z-positions z1, z2 and z3 are shown of the sequence of 2D cross section images 1000. The random stage or SEM drifts lead to artificially enhanced line edge roughness of the metal lines 101, which are extended in z direction or large variations of the width of the metal lines 102, which are extended in parallel to the z-direction.

It is a common method to derive the lateral position of each slice as well as the distance from layer to layer with the help of so called fiducials. U.S. Pat. No. 9,633,819 B2 discloses an alignment method based on guiding structures (“fiducials”) exposed to the top of the sample. FIG. 3 illustrates the alignment with fiducials. As will be explained below in more detail, marker structures 21 and 22 are formed into a deposition material 20 on top of the sample perpendicular to the direction of the cross sections before the FIB cutting of intersections 52, 53 and 54 begins. After slicing and imaging the cross sections, each cross section image contains also a cross section image segments 25 and 27 of the fiducials or alignment markers 21 and 22. The first central markers 21 are used to perform the lateral alignment amongst the slices while the distance between the two outer, second makers 22, leading to two cross section image segments 27, is used to calculate the distance between each slice.

U.S. Pat. No. 7,348,556 discloses a method to derive the line edge roughness based on a fiducial. Here, the fiducial is either already present on the surface of the workpiece or probe, or is milled at the location within a field of view.

However, the precision by using the fiducials is limited by the fiducial generation process as well as the measurement precision of the charged particle optical column for measuring the fiducial position. The fiducial markers are coarse and may measure several 20 nm up to 100 nm and may also change arbitrarily their shape from the first to last slice such that the precision of the reconstruction is not sufficient for recent semiconductor structures of much smaller size and better overlay accuracy. Error! Reference source not found., explained below in more detail, shows a result of a residual reconstruction induced line edge roughness without (FIG. 4a) and with alignment (FIG. 4b). The problem of drifts of stage or charged particle beam column becomes more severe with the reduced sizes of actual structures of interest.

This and other effects lead to artificially inhomogeneous edge shapes and positions and limit the precision metrology of interconnected circuit patterns. In a 3D-reconstruction, wavy metal lines are created and for example a line edge roughness measurement is deteriorated by alignment errors. The metrology of dimensions of a fine patterns, or the derivation of a line edge roughness or surface roughness with high accuracy of a fine 3D pattern by cross sectioning is not possible. Prior art solutions are not able to address the requirement for the recent high precision measurement for integrated circuits with minimum features sizes down to critical dimensions (CD) of 7 nm and below.

### SUMMARY

One object of the invention is a method for high precision, 3D reconstruction of 3D volume images of three-dimensional circuit pattern inspection by cross sectioning of the integrated circuits and, more particularly, to a method and apparatus for obtaining a 3D volume images of an integrated semiconductor sample free of measurement artefacts induced by stage drift, imaging column drift or image distortion.

Another object of the invention is a method for quantitative metrology of line edge positions, line edge roughness, feature dimensions or areas, for defect detection or defect review with high accuracy.

Another object of the invention is to provide a method and apparatus for inspecting an edge shape of the fine pattern and to derive a line edge roughness or surface roughness of a fine pattern with high accuracy.

According to an embodiment of the invention, the object is achieved by precision alignment of a sequence of cross section images to reconstruct a 3D tomographic data set or 3D volume image. Precision alignment includes methods for applying an alignment correction scheme and adjusting the slice positions according to the alignment correction scheme. The alignment correction scheme is based on image or feature registration. Image registration generally refers to precision placement of cross section images in 3D volumes. Image registration utilizes features of integrated circuits such as metal lines, which are present in at least a part of the cross section images. With this features, present in at least two of consecutive cross sections images, the relative lateral position and rotation of the two consecutive cross sections images can be determined with high accuracy. With the feature-based alignment, a higher accuracy can be obtained by the positions of features of integrated circuits, which are fabricated with high precision of current integrated semiconductor fabrication techniques.

In another embodiment of the invention, the accuracy is improved by statistical methods, such as centroid extraction of features of structures present in integrated semiconductor samples, such as gates, metal interconnects or vias. Other statistical methods can include averaging of measurement positions of several image features, or may consider outliers which deviate to much relative to a statistical expectation value. Thereby, a subpixel accuracy of the image alignment of individual cross section images can be achieved. Thereby, image registration of 2D cross section images is achieved in 3D volume images with high, sub-pixel accuracy.

According an embodiment of the method and apparatus of the invention, influences of a lateral stage drifts as well as errors of the scanning charged particle image acquisition method are reduced.

According an embodiment of the method and apparatus of the invention, imaging aberrations such as distortion errors of the scanning charged particle imaging method and apparatus can be extracted and removed by image processing, utilizing the features or structures of integrated semiconductor samples. According an embodiment of the method and apparatus of the invention, low-order distortion aberration changes between consecutive image slices can be extracted and removed from the cross section images. Another embodiment of the invention involves a cross section technique forming cross section images at an inclined angle deviating from 90° to the extension direction of metal interconnects in at least one metal layer.

Another embodiment of the invention involves a cross section techniques forming cross section images at an inclined angle deviating from 90° to at least one metal layer. In this embodiment, cross section images and centroids of vias can be derived from the cross section images at inclined angle.

Another embodiment of the invention comprises a method of obtaining a 3D volume image of an integrated semiconductor sample, characterized by obtaining at least a first cross section image and a second cross section image parallel to the first cross section image, wherein obtaining the first and second cross section images includes subsequently removing a cross section surface layer of the integrated semiconductor sample with a focused ion beam to make a new cross section accessible for imaging, and imaging the new cross section of the integrated semiconductor sample with a charged particle beam, and obtaining a fine alignment of the at least first and second cross section images by image registration of each of the at least first and second cross section images, wherein the image registration is performed based on of one common features of the integrated semiconductor sample in the at least first and second cross section images.

Another embodiment of the invention comprises a method of obtaining a 3D volume image of an integrated semiconductor sample, characterized by obtaining a sequence of N cross section images,
wherein obtaining the sequence of N cross section images includes subsequently removing a cross section surface layer of the integrated semiconductor sample using a focused ion beam to make a new, subsequent cross section accessible for imaging, and imaging the subsequent cross section of the integrated semiconductor sample with a charged particle imaging device. Each of a cross section image planes of the sequence of N cross section images is oriented perpendicular to a z-direction, and the integrated semiconductor sample is arranged that the direction parallel to a set of L metal lines of at least one metal layer Mk or vias of the integrated semiconductor sample forms an angle with a cross section images plane, and at least a subset of the sequence of N cross section images comprises cross section image segments of the L metal lines or vias. The method includes extracting a position P (x,y;l) of each of the cross section image segments of the l=1 to L metal lines, forming traces T (x,y;z;l) of the positions P (x,y;l) through the z-direction of at least a subset of the sequence of N cross section images, and decompose the traces T (x,y;z;l) into an average common wavy structure TA (x,y;z) and a residual deviation dT (x,y;z;l). The position of at least the subset of the sequence of N cross section images within the 3D volume image is corrected by displacing the subset of the sequence of N cross section images with the common wavy structure TA (x,y;z).

### BRIEF DESCRIPTION OF THE DRAWINGS

FIG. 1 is an illustration of the cross section imaging technique.

FIG. 2 is an illustration of cross section images and two examples of intersection images through the 3D volume image.

FIG. 3 is an illustration of the fiducial alignment process as described in prior art.

FIG. 4 is an illustration of the result of fiducial based alignment at the example of an intersection image at the example of a metal layer M1.

FIG. 5 is an illustration of the cross section image technique utilizing the feature based alignment.

FIG. 6 is an illustration of traces of image features through a stack of cross section images comprising 400 cross section images.

FIG. 7 is an illustration of the improvement achieved by an embodiment of the feature-based alignment, at the example of a metal layer M1.

FIG. 8 is an illustration of the improvement achieved by an embodiment of the invention at the example of a gate layer.

FIG. 9 is an illustration of the improved line edge roughness derivation by an embodiment of the invention.

FIG. 10 is an illustration of a slice-to-slice distortion deviation.

FIG. 11 is an illustration of another embodiment of the feature based alignment for cross section imaging with cross sections inclined to the metal interconnects in at least on metal layer.

FIG. 12 is an illustration of another embodiment of the feature based alignment for cross section imaging with cross sections inclined to the metal layers to reveal cross section images of vias.

### DETAILED DESCRIPTION

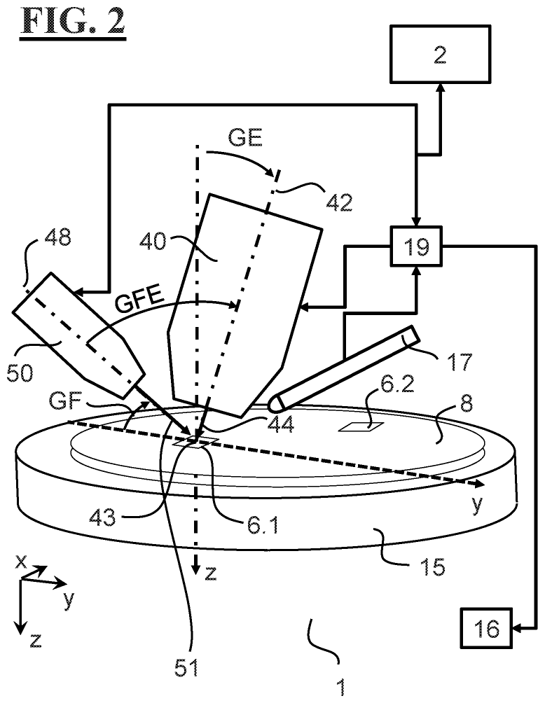

FIG. 2 shows a schematic view of the cross section image approach to obtain a 3D volume image of an integrated semiconductor sample. With the cross section approach, three dimensional (3D) volume image acquisition is achieved by a “step and repeat” fashion. First, the integrated semiconductor sample is prepared for the subsequent cross section image approach by methods known in the art. Throughout the disclosure, “cross section image” and “slice” will be used as synonyms. Either a groove is milled in the top surface of an integrated semiconductor to make accessible a cross section approximately perpendicular to the top surface, or an integrated semiconductor sample 10 of block shape is cut out and removed from the integrated semiconductor wafer. This process step is sometimes referred to as “lift-out”. In a step, a thin surface layer or “slice” of material is removed. For sake of simplicity, the description is shown at such a block shaped integrated semiconductor sample 10, but the invention is not limited to block shaped samples 10. This slice of material may be removed in several ways known in the art, including the use of a focused ion beam milling or polishing at glancing angle, but occasionally closer to normal incidence by focused ion beam (FIB) 50. For example, the focused ion beam 51 is scanned along direction x to form a cross section 52. As a result, a new cross section surface 11 is accessible for imaging. In a subsequent step, the newly accessible cross section surface layer 11 is raster scanned by a charged particle beam (CPB), such as a scanning electron microscope (SEM) or a FIB (not shown). The imaging system optical axis can be arrange to be parallel to the z-direction, or inclined at an angle to the z-direction. CPB systems have been used for imaging small regions of a samples at high resolution of below 2 nm. Secondary as well as backscattered electrons are collected by a detector (not shown) to reveal a material contrast inside of the integrated semiconductor sample, and visible in the cross section image 100 as different grey levels. Metal structures generate brighter measurement results. The surface layer removal and the cross section image process are repeated trough surface 53 and 54 and further surfaces at equal distance, and a sequence of 2D cross section images 1000 through the sample in different depths is obtained so as to build up a three dimensional 3D dataset. The representative cross section image 100 is obtained by measurements of a commercial Intel processor integrated semiconductor chip with 14 nm technology.

With the method, at least a first and second cross section images includes subsequently removing a cross section surface layer of the integrated semiconductor sample with a focused ion beam to make a new cross section accessible for imaging, and imaging the new cross section of the integrated semiconductor sample with a charged particle beam. From the sequence of these 2D cross section images 1000, a 3D image of the integrated semiconductor structure can be reconstructed. The distance dz of the cross section images 100 can be controlled by the FIB milling or polishing process and can be between 1 nm and 10 nm, preferably about 3-5 nm.

FIG. 2 shows an example of two x-z-intersection images from the 3D volume image or 3D data set obtained from a sequence of N=400 image slices or cross section images 1000 obtained in x-y-direction, and spaced in z-direction by distance dz. For sake of simplicity, only three cross section images 100.1, 100.2, 100.3 are illustrated. The random stage or SEM drifts between acquisition of the N=400 image slices lead to artificially enhanced line edge roughness in z-direction, visible in the metal lines 101 extended in z-direction, or large variations of the widths of metal lines 102, oriented perpendicular to the z-direction.

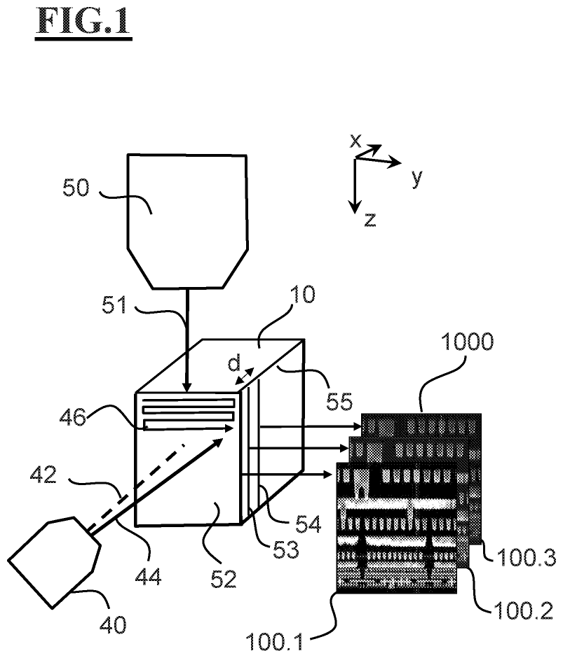

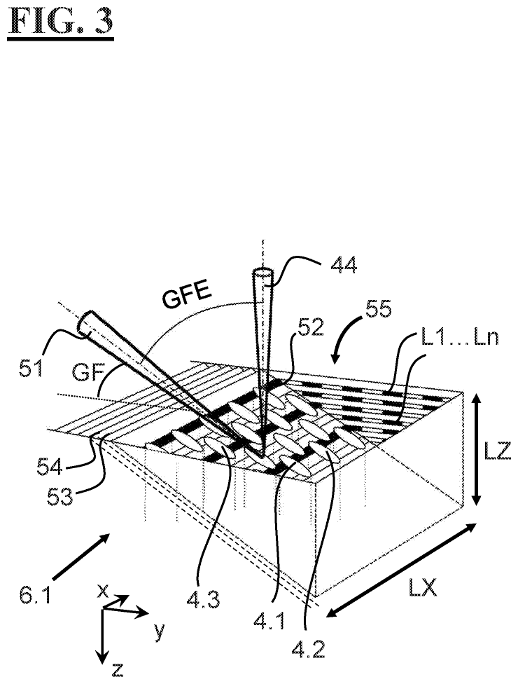

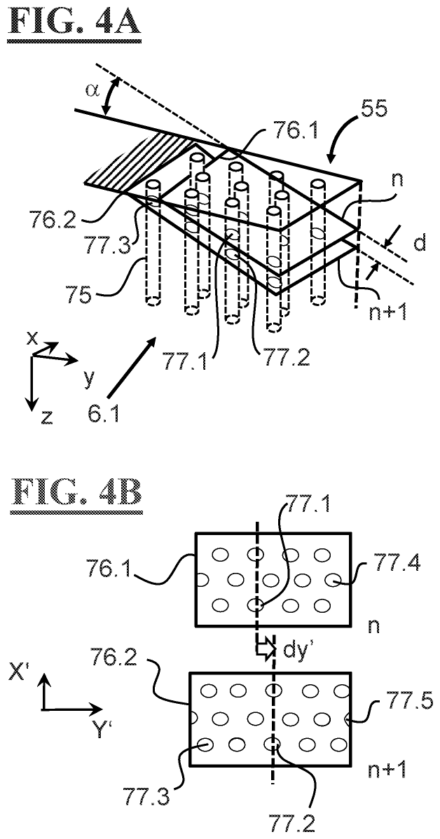

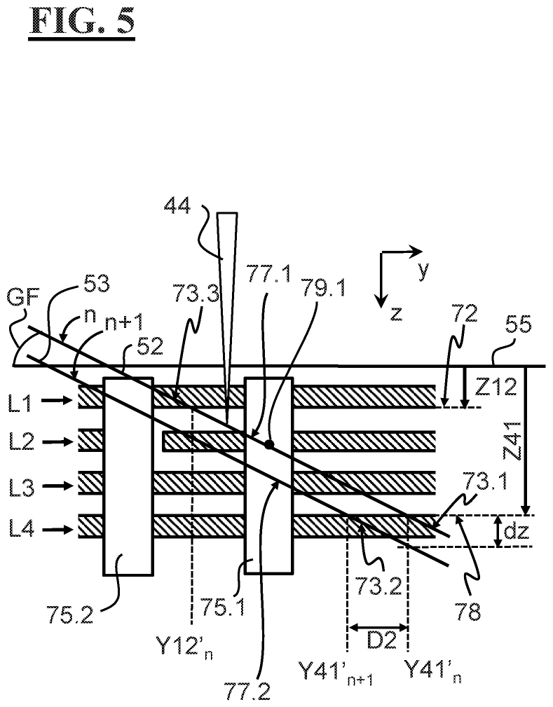

FIG. 3 illustrates the alignment with fiducials, according to prior art. Illustrated in FIG. 3a, a marker structure or fiducials are formed on top of the sample perpendicular to the direction of the cross sections before the FIB cutting of intersections begins. For the marker structure, first a material 20 is deposed on the top surface 55 of the integrated semiconductor sample. In this material, alignment marks such as parallel lines 21 and inclined lines 22 are formed by FIB processing. FIG. 3b shows an image of a typical alignment structure of the prior art. After slicing and imaging the cross section 11 by raster scanning along raster scanning lines 82, each cross section image 100 contains also a cross section image segment of the fiducials or alignment makers. Illustrated in FIG. 3c is a representative cross section 100. The central markers are visible via their cross section image segments 25 and are used to perform the lateral alignment in x-direction amongst the slices while the distance between the two cross section image segments 27 of the two outer makers 22 is used to calculate the distance dz between each slice. Error! Reference source not found. shows a result of a reconstruction induced residual line edge roughness for the M1 layer of an integrated semiconductor sample. As in FIG. 2, the images are x-z-intersection images, derived from a sequence of N=400 image slices or cross section images each obtained in x-y-direction. FIG. 4a shows a result of an x-z-intersection image without image slice alignment, and FIG. 4b shows the result with image alignment based on the fiducials. The random stage or SEM drifts between acquisition of the N=400 image slices lead to artificially enhanced line edge roughness in z-direction. The improvement by fiducial alignment is clearly visible by a reduction of image blur and reduction line edge roughness of the gate structures in the gate layer. An embodiment of the invention for fine alignment based on features or structures in the integrated semiconductor sample is described in of FIG. 5. Integrated semiconductor samples as shown in e.g. FIG. 1 consist of (K+1) metal layers (usually referred to as M0, M1, M2 . . . . MK counted from the silicon substrate level to the wafer top level) and via layers (usually referred to V0, V1, V2) which are used to connect the metal layers through columnar structures.

FIG. 3a shows a simplified example for two cross section images of an integrated semiconductor sample with metal layers, here for sake of simplicity only three metal layers M0, M1 and M2 are illustrated. The metal layers M0 and M2 comprise metal interconnections 62.1 and 62.2 parallel to the N cross section images, from which two are illustrated by n and n+1. The metal layers M1 comprise metal interconnections 61 which are at an angle of 90° to the cross section images n and n+1. The coordinate system is selected to form subsequent first and second cross section images 110 and 111 in x-y direction and perpendicular to the z-direction. The integrated semiconductor probe is thus oriented that at least a number of L metal lines or interconnects are oriented parallel to the z-direction and thus perpendicular to the cross section image planes parallel to the x-y-plane. Generally, at least a number of L metal lines or interconnects forms a predetermined angle with a cross section image plane, such that cross section image segments of each of the L metal lines are formed in at least a sequence of the N cross section images. In the embodiment of FIG. 5, the predetermined angle is 90°.

FIG. 5b illustrates two of the cross section images with z-index n (110) and n+1 (111). Generally, the cross section images 110, 111 are oriented in the x-y-plane, and the sequence of cross section images or slices are stacked or displaced in z-direction by distance dz between 1 nm-7 nm. Since the cross section cutting or slicing was performed at a predefined angle of 90° to the metal lines 61 in layers M1, it is possible to identify the cross sections image segments 64 of the corresponding metal lines 61 in layer M1 in every slice image and furthermore to extract their positions P (x,y;l), for example by centroid computation or computation of center of gravity C (x,y) of each cross section image segment of each of the 1=1 . . . . L metal lines. Metal layers M0 and M2 are only visible as cross section mage segments 63 in the case where the cross section image 110 intersect the corresponding metal interconnects 62.1 or 62.2 parallel to the cross section images 110 or 111.

FIG. 4c shows an example for a cross section image of an integrated semiconductor sample with logic structures. Metal layers (M0-M7) alternate with via layers (V0-V6) are indicated. Beneath M0, a gate layer GL are visible. The metal and gate layers comprise metal lines or interconnections either parallel or perpendicular to the cross section images. Since the cross section cutting or slicing is performed perpendicular to the metal lines in layers M1, M3, M5, . . . it is possible to identify the cross sections of the corresponding metal lines in that layers in a large set of subsequent cross section images or slices and the centroids of the metal interconnects can be computed. At least a major part of the metal interconnections perpendicular to the cross section image, as for example in M1, M3, M5 or M7 are invariant over a large number of subsequent cross section images. The cross section image through the sample shows only a few via, one example is marked with a white circle 65.

The cross section image segments of the perpendicular metal lines in layers M1, M3, . . . , M7 can be extracted by image processing such as corner or edge detection, thresholding, or morphologic operations. Positions of detected metal lines can be computed based on centroid computation or computation of center of gravity. Alternatively, position determination of metal lines can be achieved by for example feature based registration. Generally, pattern recognition and position detection techniques, also called feature registration, can employ comparison of design shapes to the cross section image segments of the metal lines, or of reference cross section image segments of metal lines or interconnects. Feature registration can employ image correlation with a reference cross section image segment of for example a metal line, or can be based on the Euclidean image distances between the cross section image and a reference cross section image segment of for example a metal line. Those skilled in the art will be able to use methods equivalent to the above mentioned methods for the position computation of the cross section image segments of metals lines.

In FIG. 5c, the boundary lines of the cross sections of metal lines are indicated by white dotted lines. The positions P (x,y;l) of each metal interconnect are evaluated (indicated by the dots) as the centroids within each boundary line. FIG. 5d shows as result of the extraction the edge shapes or boundary lines of the metal lines in layers M1, M5 and M7 together with their centroids C (x,y;l) (dots), with one example highlighted (edge shapes or boundary lines 66 of a metal line in layers M7 together with centroid 67).

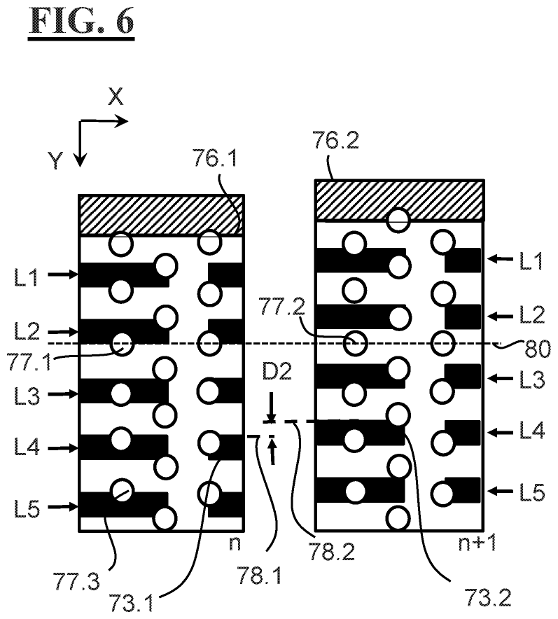

By connecting the centroids of the metal lines from slice to slice the traces of the centroids T (x,y;z;l) through z direction or a sequence of cross section images can be generated. FIG. 6 shows the traces of the centroids of the metal interconnects in layers M1, M3 and M7 for N=400 cross sections images (z-direction). Two examples 68 and 69 of several traces T (x,y;z;l) for matel layers M1 and M7 are highlighted, respectively. Since the metal interconnects are fabricated with high precision, the traces show a large common or average wavy structure TA (x,y;z) and residual deviations dT (x,y;z;l) from the common or average wavy structure TA (x,y;z). The large common or average wavy structure TA (x,y;z) represents the measurement error, induced by stage drift or imaging aberrations and comprised a common displacement vector and rotation angle error for each z-position in the 3D dataset of the sequence of N=400 cross section images. For sake of simplicity, here only the displacement error is illustrated, and the rotation error can be considered by for example rotation matrices. By extracting the common wavy component TA (x,y,z) of the traces, for example by statistical evaluation over at least a subset the L traces T (x,y;z;l), a major part of x-y misalignment for each cross section image slice at position z can be corrected in a fine alignment correction and slice registration within the 3d volume image dataset.

The extraction of the common wavy component TA (x,y,z) reveals an x-y-displacement vector (x,y) for each cross section images slice at position z, which is based on statistical evaluation of the lateral cross section image displacement. The statistical evaluation improves the accuracy and reduces errors of few individual structures or alignment marks such as the fiducials. Statistical evaluation includes for example averaging, centroid computation and can consider outliers. Examples are averaging of line edges by averaging multiple line edge points, the centroid computation, feature based registration or the statistical averaging over a set of multiple centroid points. Image processing algorithms and registration algorithms can be applied in order to remove artefacts or outliers by comparison of the feature or structure sets between two consecutive cross section images.

It should be mentioned, that the metal lines do not need to extend through the whole measured volume. As illustrated in FIG. 6, not all metal interconnects extend through all N cross section images. Gaps in metal interconnections such as in the M1 traces 68 can be identified and bridged by for example M7 traces 69. Generally, gaps can be bridged by other metal lines such that an alignment of the whole measured volume becomes possible. Only in the rare cases where all metal lines end at the same position, the reconstruction is not able to register the part before and after the gap properly. However, in these cases, a registration is not necessary.

Since one method of the invention relies on structures present in the integrated semiconductor sample to be extracted from the cross section images or the raw 3D stacks, the method of the invention is referred to as “structure-based” alignment in contrast to the “fiducial-based” alignment of the prior art. The precision alignment of 2D cross section images slices in a 3D volume image is also referred to as registration or image registration.

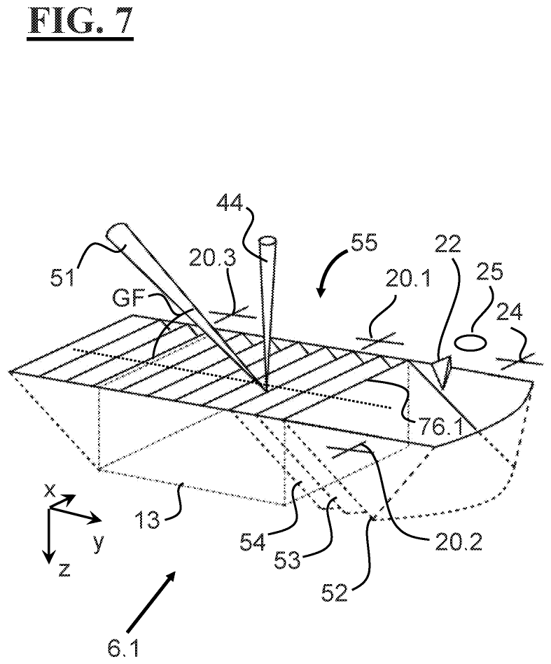

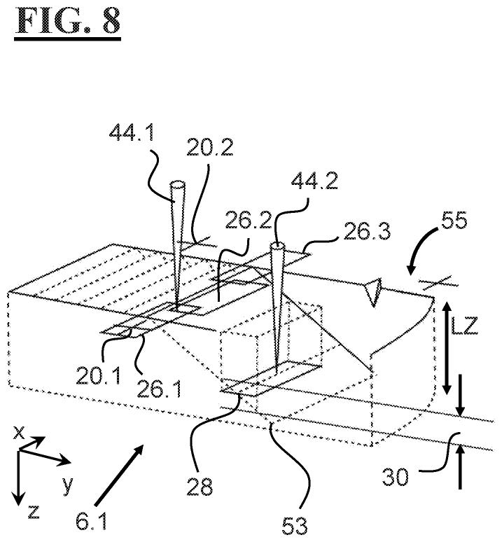

Comparisons between fiducial based alignment and structure-based alignment are shown in Error! Reference source not found, and FIG. 8. FIG. 7 shows the same cross section in x-z direction through the M1 layer as illustrated in FIGS. 4a and b, but shows the cross section after the structure-based alignment. FIG. 8a shows a cross section in x-z direction through the gate layer, reconstructed from N=400 cross section images, each obtained in x-y direction, after alignment based on fiducials. FIG. 8b shows the same cross section through the gate layer after the structure-based alignment. The improvement in reduced line edge roughness induced by misalignment or coarse alignment by fiducial-based alignment alone is clearly visible in both images of FIGS. 7 and 8b and becomes more visible at lower layers with finer structures, such as the gate layer.

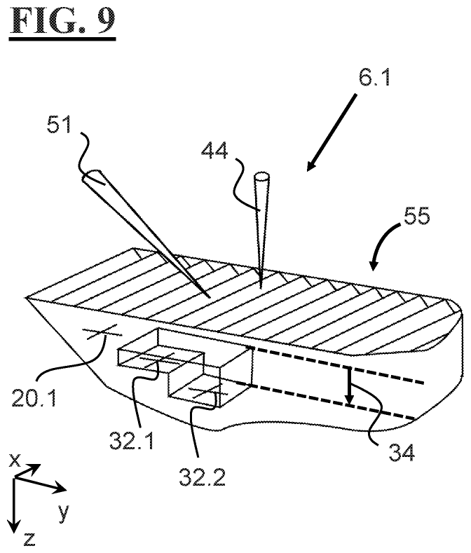

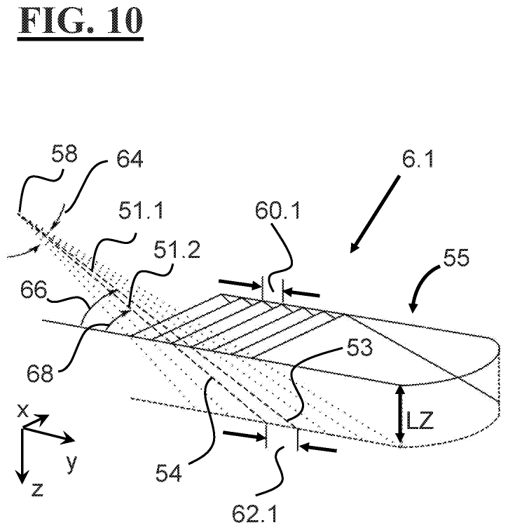

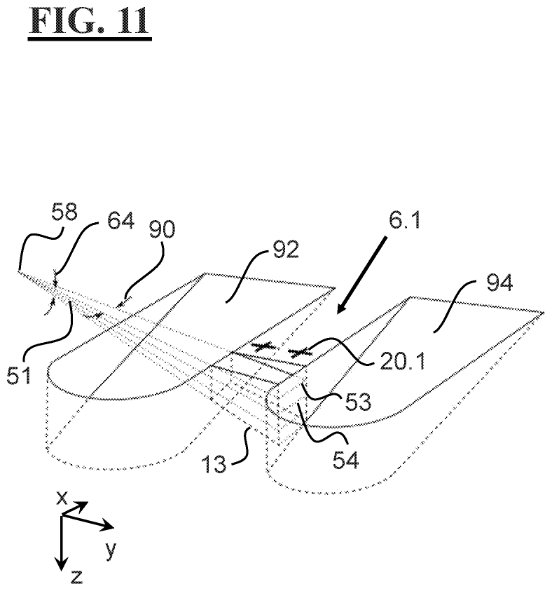

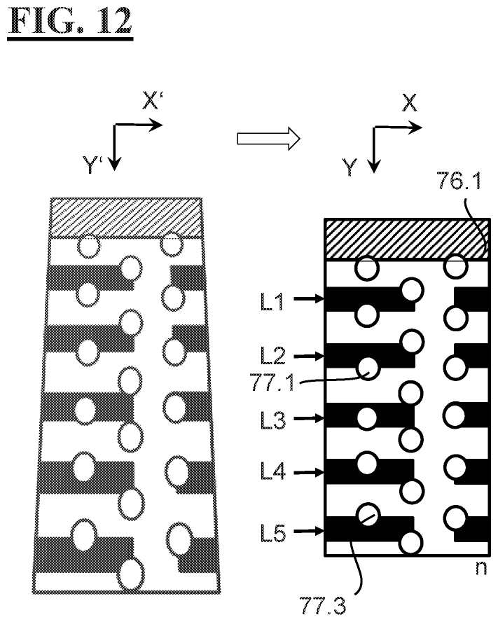

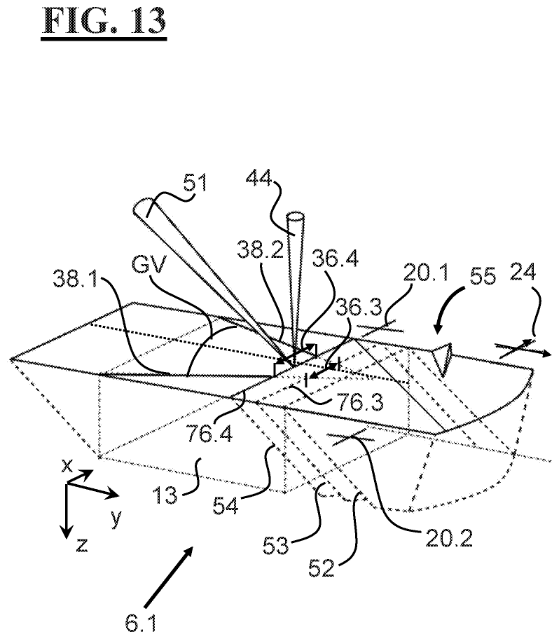

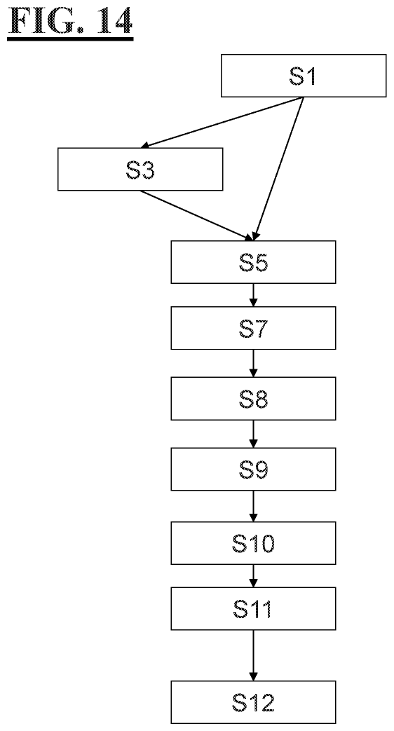

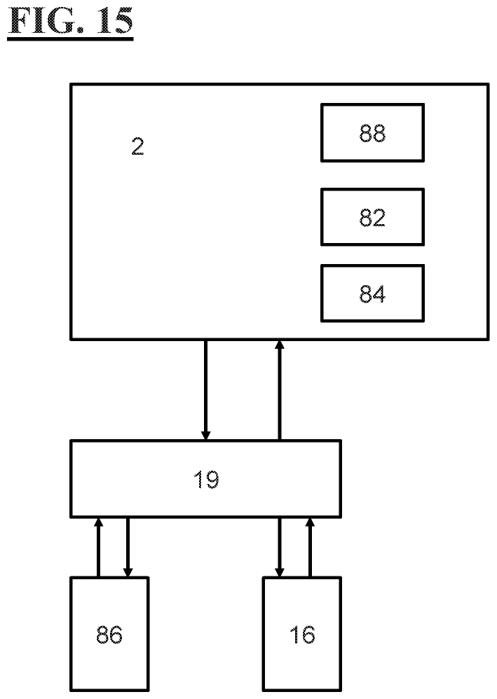

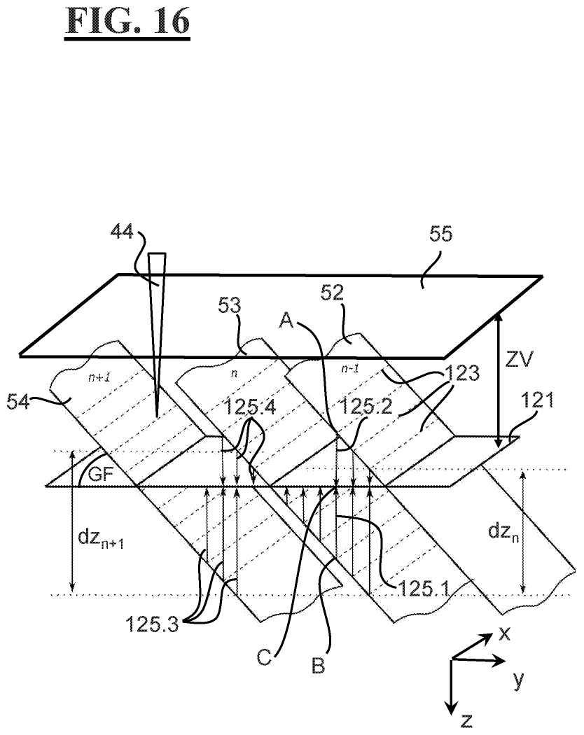

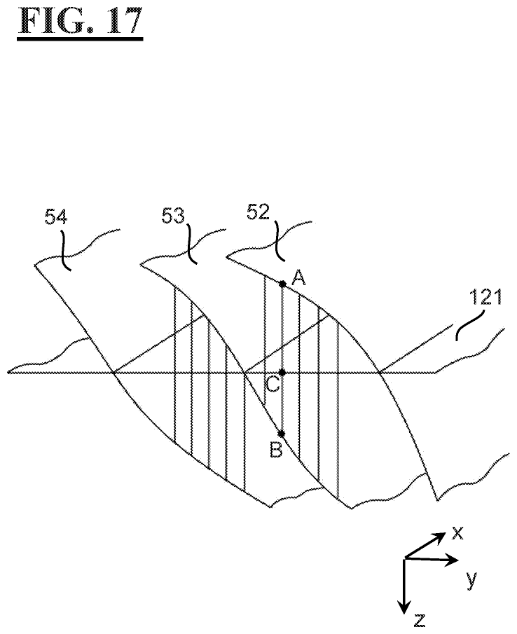

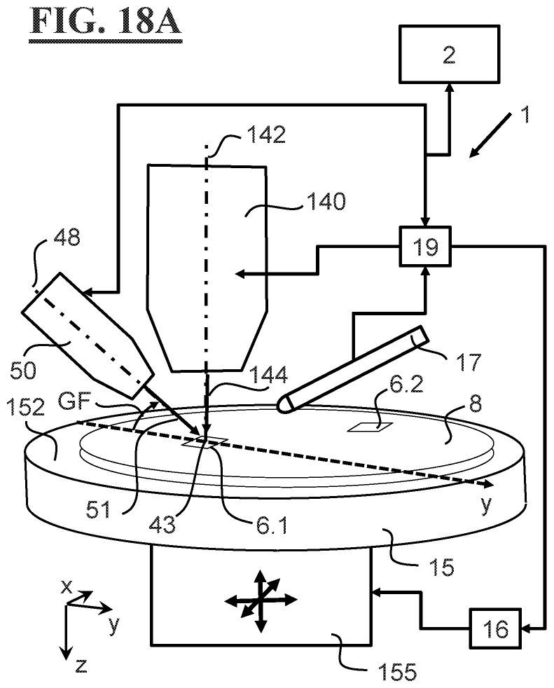

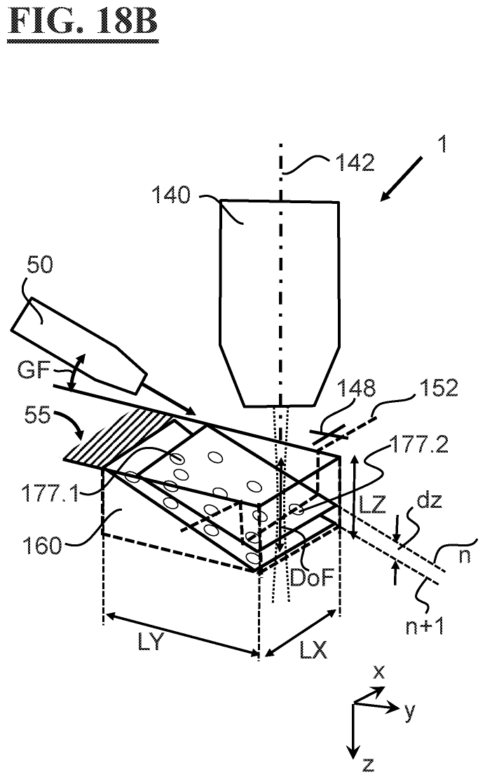

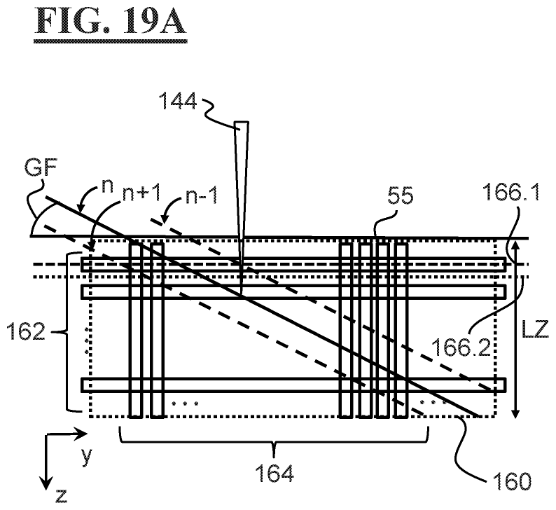

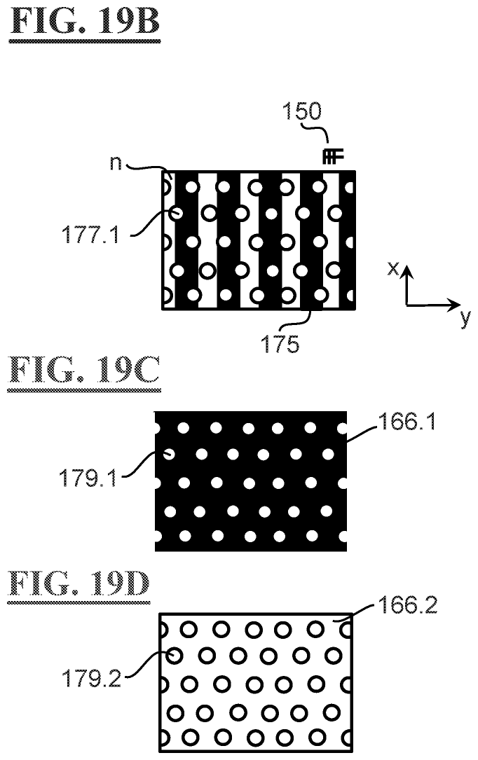

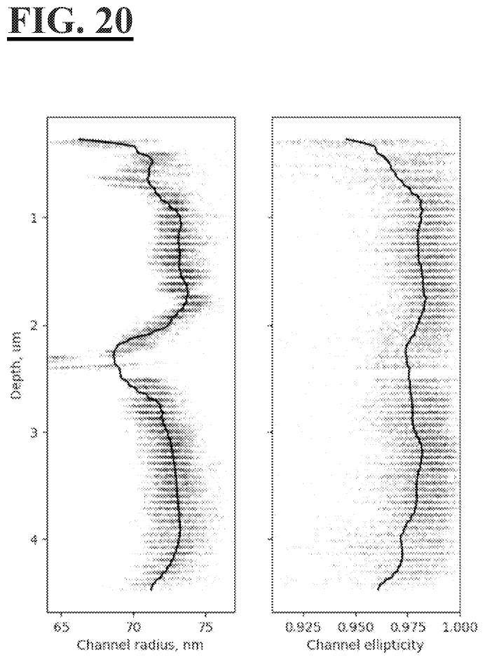

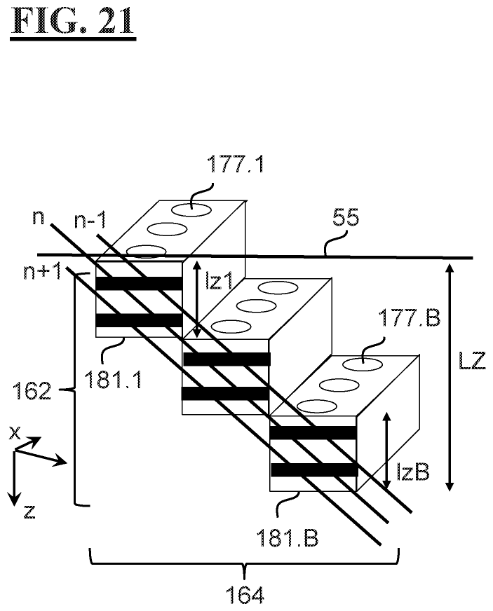

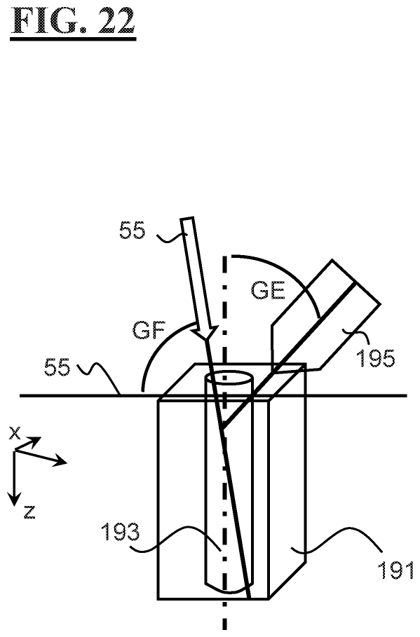

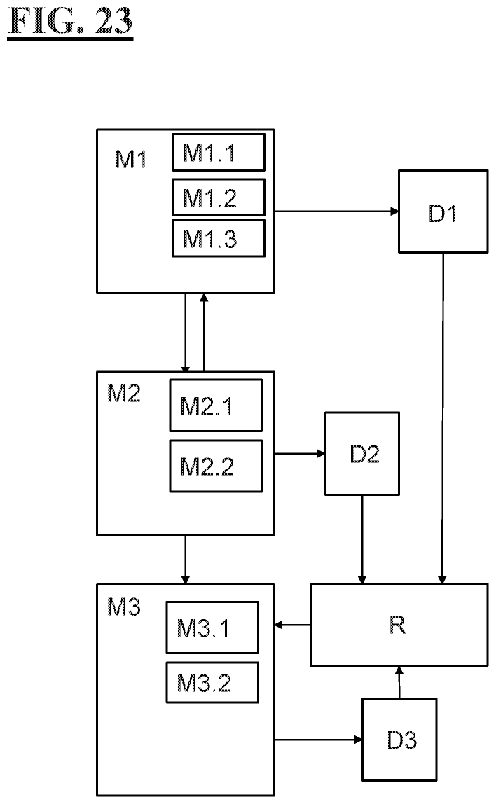

A quantitative comparison of the improvement can be achieved through extracting a contour and calculating the standard deviation of the contour from its mean value. From the examples in FIG. 9, a measure for line edge roughness is extracted from two images. FIG. 9a shows the example of a line segment 91 for fiducial-based alignment, FIG. 9b shows the example of a line-segment 92 as a result for structure-based alignment. In the example for the fiducial based alignment, the standard deviation of the line edge 91 is 24.26 nm, while in FIG. 9b, with the structure-based alignment, the standard deviation of the line edge 92 is reduced by a factor two to 12.8 nm. Generally, the standard deviation can be reduced by structure-based alignment by a factor 1.5-3. The residual measured line edge roughness is thus reduced from artificial misplacements from residual aberrations or alignment errors from the measurement of the fiducials. In an equivalent way, surface roughness values are reduced from artificial misplacements, and the precision of size or dimension measurements for example of a metal line width or gate dimensions can be improved by a factor 1.5-3 with feature-based alignment. Another embodiment is illustrated in FIG. 10. After the correction of the x-y alignment with image registration based on structure- or feature based alignment there may be still some residual drifts of the traces from slice to slice. These drifts may be attributed to a drifting SEM image distortion. Using the residual displacement vectors 300 of the centroids, for which one example is illustrated as 302, image distortion may be determined by for example approximation or fitting with some reasonable basis functions of image distortion, such as low order pin-cushion, toroidal distortion, shear or keystone distortion. These basis functions can be described by x-y-vector polynomials. With the extracted basis functions for distortion, each cross section image can be corrected by subtraction of image distortions to obtain a slice to slice or absolute relative image distortion correction. The distortion correction can be obtained on a slice to slice basis or can involve more than two or all image slices to derive an average distortion and a residual distortion deviation for each individual image slice. FIG. 10 illustrates an example for the extraction of a distortion field, comprising distortion vectors 300 around the centroids, of which one is labelled by 302. The cross section centroid determination might produce some outliers. Two examples are indicated by number 301. Outliers can be removed e.g. by image comparison or by statistical analysis, or will be suppressed by polynomial fitting of low order distortion polynomials. The systematic distortion change from slice n=80 to slice n=81 in y-direction can be fitted to the reasonable distortion basis functions and applied for correcting the relative distortions from slice to slice. In this example, the low distortion is dominated by a symmetrical barrel distortion in y-direction with an image field dependency proportional to y, and constant in x-direction. The maximum relative change of distortion between slice n=80 and slice n=81 is about 19 nm. Generally, the typical relative distortion change from image to image can be 0-30 nm. The distortion correction can be performed before the feature-based alignment, after the feature-based alignment or can be an integral part of the feature-based alignment with the alignment displacement vectors TA (x,y;z) or rotation vectors as distortion vectors of lowest order for each cross section image at position z.

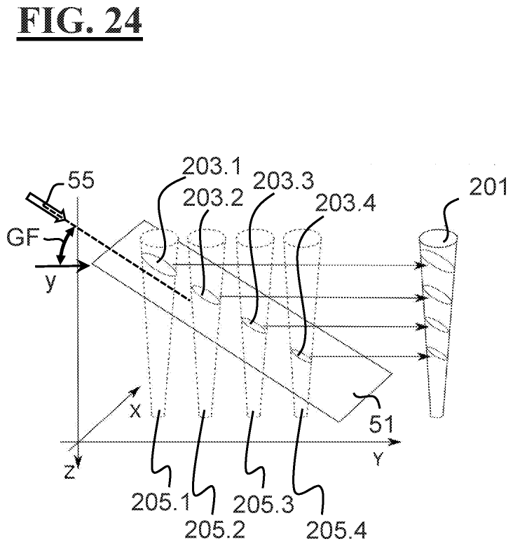

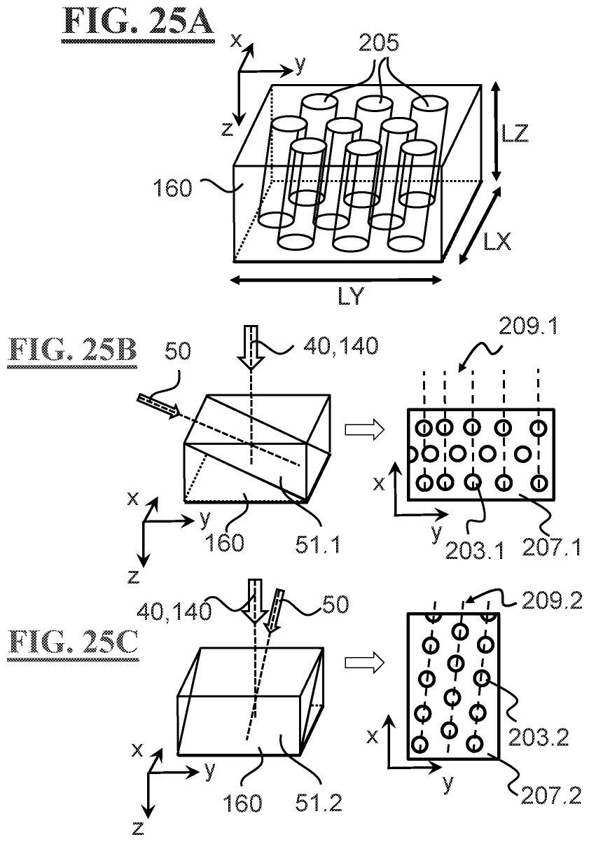

Another embodiment method is illustrated at FIG. 11a. In this embodiment, the integrated semiconductor samples are cut under a predefined angle. The predefined angle describes the angle between for example the metal interconnects 71 in layer M0 and the cross section x-y-plane. The predefined angle can for example be 45°, but also other angles such as 30° or 60° are possible. The cross section images 210 and 211 through the metal interconnects 71 in layers M0-M2 are thus at an predefined angle to the metal lines or interconnects, and the position of each metal interconnect in the metal layer M0-M2 change for each slice 210, 211 in a controlled and equal manner, depending on the slicing distance dz and the predetermined angle of the metal interconnects in that layer of the integrated semiconductor sample. The metal interconnects 72 are elongated perpendicular to the metal interconnects 71 and form such a second angle of 90° minus the predetermined angle with the cross section image plane, in this example with predetermined angle of 45° the second angle is also 45° (=90°-45°). The M0 and M2 metal interconnects 71 “move” block wise to the left from slice 210 to slice 211, while the metal interconnects 72 of layer M1 “move” block wise to the right. Extracting the traces of the positions for the metal lines according to any methods described above leads to bunches of traces running from right to left (metal interconnects in layer M0 and M2 in cross sections 210, 211) and traces running from left to right (metal interconnections in layer M1 in 210, 211). This is illustrated at two examples of cross section images 210 and 211 in FIG. 11b. From the relative distance change of cross section image segments 73.1 and 73.2 of metal interconnects 71 in layer M0 or M2 and of cross section image segments 74.1 and 74.2 of metal interconnects 72 in layer M1, which change their position in opposite direction, the slice thickness dz can be derived with high precision. As described above, due to the statistical evaluation utilizing for example a large number of metal traces and the high precision of the fabrication of metal interconnects, the z-position determination is obtained with higher precision as for fiducial based alignment. From the traces of the positions of the metal lines, detected as described above, the linear displacement of the metal lines according to the predetermined angle and second angle can be extracted and a residual common wave signature of the traces can be extracted. This common wave signature is used for feature based alignment as described above. Using the method of cross section imaging under a predefined angle to the metal interconnects therefore enables the structure-based alignment in x, y, and z-direction with superior precision to pure fiducial based alignment. In addition, in the case of cross section imaging at an angle to the metal interconnects, the regular and predetermined positional change of the metal interconnects in each cross section image can be separated and isolated from distortions as described above, and registration of 2D cross section images in the 3D volume image can be obtained with high accuracy.

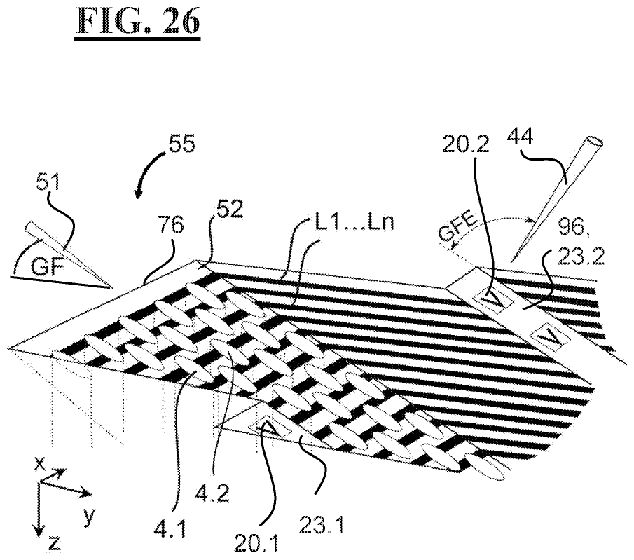

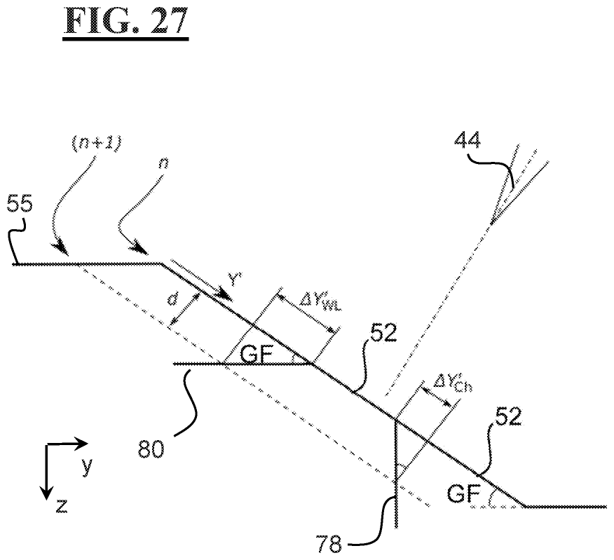

In the above embodiments, the cross section image planes are oriented perpendicular to the top surface 55 of the integrated semiconductor wafer, with the normal to the wafer top surface 55 oriented parallel to the y-direction, as shown in FIG. 1. This results in 2D cross section images which are oriented parallel to the y-direction, or, in other words, the cross section image planes include the y-axis or wafer normal axis, and the slicing direction z is perpendicular to the y-axis or wafer normal axis. In another embodiment of the invention, the intersection angle of the cross section image planes is inclined to the wafer normal at a predefined inclination angle, and the slicing direction z is not perpendicular, but inclined at a predefined inclination angle to the y-axis or wafer normal axis. In an example, illustrated in FIG. 12a, metal layers M0-MK as well as the vias, with one example referred to by number 75, which are interconnections through at least two metal layers, become visible in the cross section images. As in the example above, the metal interconnects or vias are oriented in a direction at a predefined angle to the cross section image planes, such that cross section images of the metal interconnects and vias become visible in the cross section images. Positions of metal interconnects and vias can be detected by the image processing methods described above, for example from their centroids. Low order distortion from imaging can be analyzed and subtracted as described above and image displacement from slice to slice can be computed with high accuracy, thereby obtaining a registration of each 2D cross section image slice in the 3D volume image with high precision. FIG. 12b shows two examples of two 2D consecutive cross sections images with indices n and n+1, with cross section image segments of vias indicated by 77.1 and 77.2. The top boundary surface of the integrated semiconductor structure (see reference number 55 in FIG. 12a) is indicated by reference number 76.

The superior precision alignment of the embodiments becomes evident when considering several advantages of the embodiments of the invention. First, the metal lines, gates and vias are running each in known planes and under known angles at 90° to each other, respectively, and are manufactured with much more elaborated fabrication technologies than any fiducial marks can be fabricated. Semiconductor fabrication technologies, such as immersion lithography exposure, metal deposition or ion implantation, directed RIE etching, and polishing for integrated circuits are tailored to critical dimensions of few nm, for example 7 nm, 5 nm or 3 nm in near future, and result in a typical pattern placement or overlay accuracy below 2 nm or even below 1 nm precision for the lowest and finest layers such as gate layers and lower metal layers such as M0. Generally, the overlay accuracy of metal interconnects is about a factor ⅓ better than the shortest dimension of the metal lines, and as a consequence, the low metal layer and gate layer overlay accuracy is in the order of or below 1 nm. The position accuracy or placement and dimensions of the gates or metal interconnects is thus much better than the typical fiducials produced by the coarse FIB assisted deposition process, with FIB beam diameter in the order of for example 20 nm and FIB scanning positioning accuracy of above 3-5 nm. The metal interconnects of recent integrated semiconductor samples with minimum feature sizes (CD) of few nm, such as 5 or 3 nm, allow thus a feature based alignment which is at least a factor 3 improved over a fiducial based alignment of the prior art. As a result, the position computation, such as the centroid computation for metal interconnects or gates leads to a much higher precision and the displacement of the cross section images can be determined much more precise compared to the position of fiducials. The extraction of the metal interconnects with image processing techniques, optional in combination with the evaluation and subtraction of image distortions, lead such to an improved precision alignment of cross section images via feature or structure based registration.

Second, from the cross section images the position of a metal interconnect, a via or a gate is derived for example from a contour line. The computation for example of the centroid of a single common feature in two subsequent slices includes statistical averaging and is thus more robust to e.g. image noise and thereby improves accuracy of the alignment of the two image slices. Third, the typical larger number L of metal interconnects, for example two, five, 10 or up to 100, further improves the statistics of the position determination for purposes of image registration and alignment. Line edge roughness derivation can be improved at least by a factor of 1.5, factors of 2-3 can easily be achieved. Since defects are rare they do not affect the overall quality of alignment methods using many structures at once. The statistical evaluation of feature based alignment is demonstrated to thus enable an improvement of at least factor 1.5 over the fiducial based alignment of the prior art.

In addition, defect candidates can be detected as outliers from the statistical evaluation. In another embodiment, or in addition to the described above, integrated semiconductor structures are a priory known structures. Design information or 3D CAD information can be used to improve the edge extraction of the metal interconnects and vias, the position extraction as well as image registration. For example, CAD information can be used to identify locations were metal lines end and therefore should not be visible in cross section images any more. Thereby, outliers of the image processing methods can be reduced. In addition, defect candidates can be detected as outliers from the statistical evaluation.

In another embodiment, the structure or feature-based alignment is combined with fiducial based alignment. Integrated semiconductor samples may include highly repetitive features such as gates in the gate layer, which might lead to ambiguities in the image registration. Generally, a coarse registration with fiducials formed on top of the integrated semiconductor sample can reduce the ambiguity and increase the speed of fine image registration by feature or structure-based alignment according to any of the embodiment of the invention.

Image processing methods as described above, such as corner or edge detection, thresholding, or morphologic operations, or similar operations, are well known in the art. Image processing is recently improved by the increase of computation speed for example by usage of computer clusters comprising several 100s of processors. Image processing methods to extract features or structures of integrated semiconductor samples can also involve are be replaced by Machine Learning algorithms.

The above-described embodiments are intended to be examples only. Despite the embodiments are described at the example of semiconductor structures as probes, the method may as well be applied to materials or probes of comparable structures which allow precise image registration. Alterations, modifications, variations and combinations can be effected to the particular embodiments by those of skill in the art without departing from the scope, which is defined by the claims appended hereto.

Table of Symbols

| No. | Item |
|---|---|
| 10 | Sample |
| 11 | cross section surface |
| 20 | surface depostion material |
| 21 | first fiducial markers |
| 22 | second fiducial markers |
| 25 | cross section image segments of first fiducial markers |
| 27 | cross section image segments of second fiducial markers |
| 50 | FIB-column |
| 51 | focus ion particle beam |
| 52 | first cross section surface |
| 53 | second cross section surface |
| 54 | third cross section surface |
| 55 | Sample top surface |
| 61 | first metal lines extended in z-direction |
| 62.1, 62.2 | second metal lines, extended in x-direction |
| 63 | cross section of second metal line |
| 64 | cross section of first metal line |
| 65 | cross section of a via |
| 66 | boundary line of a cross section image segment of a metal line |
| 67 | centroid of a cross section image segment of a metal line |
| 68 | traces of centroids of cross section image segment of metal lines in |
| | layer M1 through z-direction |
| 69 | traces of centroids of cross section image segment of metal lines in |
| | layer M7 through z-direction |
| 71 | first metal lines elongated in a direction forming a predetermined |
| | angle with the z-direction perpendicular to the cross section images |
| 72 | second metal lines elongated in a direction forming a second angle |
| | with the z-direction perpendicular to the cross section images |
| 73.1, 73.2 | cross section image segments of first metal lines 71 |
| 74.1, 74.2 | cross section image segments of second metal lines 72 |
| 75 | vias or metal lines perpendicular to the top surface 55 |
| 77.1, 77.2 | cross section image segments of vias or metal lines perpendicular to |
| | the top surface |
| 91 | Line edge of a metal line after fiducial-based alignment |
| 92 | Line edge of a metal line after feature-based alignment |
| 100, 100.1, | cross section image |
| 100.2, 100.3 | |
| 101 | metal lines extended in z direction |
| 102 | metal lines extended in x direction |
| 110 | first cross section image |
| 111 | second cross section image |
| 210 | first cross section image |
| 211 | second cross section image |
| 300 | Image distortion vectors |
| 301 | outliers of image distortion vectors |
| 302 | centroid of a cross section image segment of a metal line in a cross |
| | section image |
| 1000 | sequence of cross section images |

1. A method of obtaining a 3D volume image of an integrated semiconductor sample by feature based alignment, characterized by
obtaining at least a first cross section image and a second cross section image parallel to the first cross section image,
wherein obtaining the first and second cross section images includes subsequently removing a cross section surface layer of the integrated semiconductor sample using a focused ion beam to make a new cross section accessible for imaging, and imaging the new cross section of the integrated semiconductor sample with an imaging device,
obtaining a feature based alignment of the at least first and second cross section images by image registration of each of the at least first and second cross section images,
wherein the image registration is performed based on at least one common feature of the integrated semiconductor sample in the at least first and second cross section images.

2. The method of claim 1, wherein the at least one common feature comprises at least one of a metal line, a via or a gate structure.

3. The method of claim 1, wherein the image registration is performed based on two or more common features, comprising at least a metal line, a via or a gate structure.

4. The method of claim 1, wherein the statistical evaluation comprises at least one of a computation of a centroid, a feature detection or a statistical averaging.

5. The method according to any of the preceding claims, including providing a fiducial based alignment of the at least first and second cross section images by measuring and evaluation of the position of alignment marks previous to the feature based alignment.

6. The method according to any of the preceding claims, where the imaging of the new cross section of the integrated semiconductor sample is performed with one of an charged particle device, an atomic force microscope or an optical microscope

7. The method of claim 6, wherein the focused ion beam and the electron beam are arranged and operated at an angle and a beam axis of the focused ion beam and a beam axis electron beam intersect each other.

8. A method of claim 1, wherein the at least a first and second cross section images are formed perpendicular to a top surface of the integrated semiconductor sample.

9. A method of claim 8 wherein the at least a first and second cross section images are formed perpendicular to metal interconnects or gates of at least one metal layer of the integrated semiconductor sample.

10. A method of claim 8, wherein the at least a first and second cross section images are formed inclined at an angle deviating from 90° to metal interconnects or gates of at least one metal layer of the integrated semiconductor sample

11. A method of claim 1, wherein the at least a first and second cross section images are formed inclined to a top surface of the integrated semiconductor sample to reveal cross section images of at least one via perpendicular to the top surface of the integrated semiconductor sample.

12. A method of claim 1, wherein the image alignment includes subtraction of an image distortion deviation between the at least first and second cross section images.

13. A method of claim 12, wherein the subtraction of the image distortion deviation includes an approximation of the image distortion deviation by a basis distortion functions.

14. The method according to any of the preceding claims, where after the image registration the at least first and second cross section images are combined to a 3D volumetric image.

15. A semiconductor inspection device adapted to perform any the methods or the any of the preceding claims.

16. A method of obtaining a 3D volume image of an integrated semiconductor sample, characterized by
obtaining a sequence of N cross section images,
wherein obtaining the sequence of N cross section images includes subsequently removing a cross section surface layer of the integrated semiconductor sample using a focused ion beam to make a new cross section accessible for imaging, and imaging the new cross section of the integrated semiconductor sample with a charged particle imaging device,
wherein each of a cross section image planes of the sequence of N cross section images is oriented perpendicular to a z-direction, and wherein the integrated semiconductor sample is arranged that the direction parallel to a set of L metal lines of at least one metal layer Mk of the integrated semiconductor sample forms an angle with a cross section images plane, and
wherein at least a subset of the sequence of N cross section images comprises cross section image segments of the L metal lines,
extracting a position P (x,y;l) of each of the cross section image segments of the l=1 to L metal lines,
forming traces T (x,y;z;l) of the positions P (x,y;l) through the z-direction of at least a subset of the sequence of N cross section images,
decompose the traces T (x,y;z;l) into an average common wavy structure TA (x,y,z) and a residual deviation dT (x,y;z;l),
correcting the position of at least the subset of the sequence of N cross section images within the 3D volume image by displacing the subset of the sequence of N cross section images with the common wavy structure TA (x,y;z).

17. The method according claim 16, wherein the extraction of at least one position P (x,y;l) comprises at least one of edge extraction or feature detection of the cross section image of the metal line 1.

18. The method according claim 17, wherein the extraction of at least one position P (x,y;l) comprises centroid or center of gravity computation.

19. A semiconductor inspection device adapted to perform any the methods or the any of the claims 16 to 18.
